(19) United States
(12) Patent Application Publication
(10) Pub. No.: US 2019/0198821 A1
(43) Pub. Date: Jun. 27, 2019

(54) MASK FOR OLED THIN-FILM ENCAPSULATION

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wei YU, Wuhan, Hubei (CN)

(21) Appl. No.: 15/579,852

(22) PCT Filed: Oct. 27, 2017
(86) PCT No.: PCT/CN2017/107992

§ 371 Date: Nov. 19, 2018

(30) Foreign Application Priority Data
Aug. 16, 2017 (CN) 201710699482.8

(51) Int. Cl. H01L 51/56; H01L 51/52

(52) U.S. Cl. CPC H01L 51/56; H01L 51/5237

(57) ABSTRACT

The present invention provides a mask for an OLED thin-film encapsulation, including a hollow portion having an opening configured to form a thin-film encapsulation layer, a cover portion configured to cover a non-thin-film encapsulation region on a substrate, the cover portion having a first surface contacting with the substrate, and a second surface away from the substrate, the cover portion having an edge surrounding the opening and close to a side of the cover portion contacting with the substrate, and at least one portion of the edge of the cover portion formed with a beveled corner.

### FIELD OF INVENTION

The present invention relates to a mask, and more particularly to a mask for an OLED thin-film encapsulation.

### BACKGROUND OF INVENTION

OLED (organic light-emitting diode) displays are a new generation of displays. An organic thin-film emits light by forming an organic thin-film on an OLED substrate, where an organic thin-film is disposed between a cathode metal electrode and an anode metal electrode and a voltage is applied to both electrodes. OLED displays, compared to LCD displays, have the following advantages: self-luminous, fast response times, wide viewing angles, saturated colors, and many other advantages, also including being able to achieve a flexible display. For example, by using a flexible plastic substrate to be a carrier, and implement a thin-film encapsulating process, a flexible OLED panel can be achieved.

Currently, OLED thin-film encapsulations mainly adopt a structure in which an inorganic layer and an organic layer are stacked. Inorganic layer materials typically used are, for example, SiNx, SiOx, SiON, etc. Organic layer materials commonly use polymer materials. The inorganic layer is used to block water and oxygen. The organic layer mainly disperses stress generated between two inorganic layers. During implementation of the thin-film encapsulation process, a mask needs to be disposed, and there is at least one opening formed in the mask. A region of the opening can form a thin-film layer on a substrate, and the unopened region cannot form the thin-film on the substrate.

As illustrated in FIG. 3a, in order to avoid shadowing while using a mask, the mask 302 needs to be closely in contact with a substrate 301 during thin-film formation, the mask 302 forms at least one opening 304, the thin-film encapsulating material will form a continuous thin-film 303 on the substrate 301, the mask 302 and a junction of the substrate 301 and the mask 302. After the thin-film is formed, as illustrated in FIG. 3b, the mask 310 needs to be raised to facilitate picking and placing the substrate 311. In this case, the continuous thin-film 312 will be broken at the junction of the substrate 301 and the mask 302 (region A) due to the rise of the mask 310, resulting in a large number of particles being generated. Particles are an important factor of thin-film encapsulation, and when there are many particles in thin-film encapsulating, the thin-film encapsulating will very easily fail.

In summary, the mask for an OLED thin-film encapsulation according to the conventional art, the thin-film encapsulating material will form a continuous thin-film on the substrate, the mask and the junction of the substrate, and the mask. After the thin-film is formed, when the mask is raised, the continuous thin-film will be torn due to the rise of the mask, resulting in a large number of particles being generated, thereby impacting effectiveness of thin-film encapsulation.

### SUMMARY OF THE INVENTION

The present invention provides a mask for an OLED thin-film encapsulation, which can prevent the continuous thin-film tearing and resulting in a large number of particles being generated when the mask is raised, thereby ensuring the effectiveness of thin-film encapsulation.

In order to solve the above-mentioned problems, the technical solutions provided by the present invention are as follows:

The present invention provides a mask for an OLED thin-film encapsulation, comprising:

a hollow portion having an opening configured to form a thin-film encapsulation layer on a substrate; and

a cover portion configured to cover a non-thin-film encapsulation region on the substrate, wherein the cover portion has a first surface contacting with the substrate, and a second surface away from the substrate;

wherein the cover portion has an edge surrounding the opening and close to a side of the cover portion contacting with the substrate, at least one portion of the edge of the cover portion is formed with a beveled corner; an area of the first surface is smaller than an area of the second surface; and the second surface covers the first surface.

According to a preferred embodiment of the present invention, the beveled corner is a chamfered corner or a filleted corner.

According to a preferred embodiment of the present invention, the edge surrounding the opening has an inner wall formed with a first cutting point, and the first surface is formed with a second cutting point.

According to a preferred embodiment of the present invention, the beveled corner is an equilateral orthogonal beveled corner, and an angle between a line from the first cutting point to the second cutting point and a vertical direction of the mask is 45°.

According to a preferred embodiment of the present invention, a distance from the first cutting point to the substrate ranges from 15 to 20 um.

According to a preferred embodiment of the present invention, the mask for the OLED thin-film encapsulation is configured to form a gap between the thin-film encapsulation layer and an inner wall of the cover portion surrounding the opening.

According to a preferred embodiment of the present invention, the gap surrounds the thin-film encapsulation layer.

According to a preferred embodiment of the present invention, another gap is formed between the thin-film encapsulation layer formed on the substrate corresponding to a region of the opening and a thin-film encapsulation material attached on the cover portion.

According to a preferred embodiment of the present invention, the mask comprises two or more of the hollow portions, and one of the hollow portions is configured to correspondingly form one of the openings.

The present invention further provides a mask for an OLED thin-film encapsulation, comprising:

a hollow portion having an opening configured to form a thin-film encapsulation layer on a substrate; and

a cover portion configured to cover a non-thin-film encapsulation region on the substrate, wherein the cover portion has a first surface contacting with the substrate, and a second surface away from the substrate;

wherein the cover portion has an edge surrounding the opening and close to a side of the cover portion contacting with the substrate, and at least one portion of the edge of the cover portion is formed with a beveled corner.

According to a preferred embodiment of the present invention, the beveled corner is a chamfered corner or a filleted corner.

According to a preferred embodiment of the present invention, the edge surrounding the opening has an inner wall formed with a first cutting point, and the first surface is formed with a second cutting point.

According to a preferred embodiment of the present invention, the beveled corner is an equilateral orthogonal beveled corner, and an angle between a line from the first cutting point to the second cutting point and a vertical direction of the mask is 45°.

According to a preferred embodiment of the present invention, a distance from the first cutting point to the substrate ranges from 15 to 20 um.

According to a preferred embodiment of the present invention, the mask for the OLED thin-film encapsulation is configured to form a gap between the thin-film encapsulation layer and an inner wall of the cover portion surrounding the opening.

According to a preferred embodiment of the present invention, the gap surrounds a peripheral of the thin-film encapsulation layer.

According to a preferred embodiment of the present invention, another gap is formed between the thin-film encapsulation layer formed on the substrate corresponding to a region of the opening and a thin-film encapsulation material attached on the cover portion.

According to a preferred embodiment of the present invention, the mask comprises two or more of the hollow portions, and one of the hollow portions is configured to correspondingly form one of the openings.

The present invention has the following advantages: in comparison with the prior art, the present invention provides a mask for an OLED thin-film encapsulation, a side of a mask closing to and contacting with a substrate, a cover portion which has an edge surrounding an opening, at least one portion of the edge of the cover portion is formed with a beveled corner, such that the thin-film formed on the substrate is disconnected with the mask and the thin-film attached on the mask, so as to prevent a continuous thin-film from being formed between the substrate and the mask, thereby preventing the continuous thin-film tearing and resulting in a large number of particles being generated when the mask is raised, thereby ensuring the effectiveness of thin-film encapsulation.

### DESCRIPTION OF DRAWINGS

In order to more clearly illustrate the technical solutions in the embodiments or the prior art, the following drawings, which are intended to be used in the description of the embodiments or the prior art, will be briefly described. It will be apparent that the drawings and the following description are only some embodiments of the present invention. Those of ordinary skill in the art may, without creative efforts, derive other drawings from these drawings.

FIG. 1 illustrates a cross-sectional view of a mask for an OLED thin-film encapsulation according to a first embodiment of the present invention.

FIG. 2 illustrates a cross-sectional view of a mask for the OLED thin-film encapsulation according to a second embodiment of the present invention.

FIG. 3a illustrates a cross-sectional view of a mask for an OLED thin-film encapsulation in the conventional art.

FIG. 3b illustrates a partial view of a mask for an OLED thin-film encapsulation in the conventional art.

### DETAILED DESCRIPTION OF THE PREFERRED EMBODIMENTS

The structure and the technical means adopted by the present invention to achieve the above and other objects may be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, etc., are only directions by referring to the accompanying drawings, and thus the used directional terms are used to describe and understand the present invention, but the present invention is not limited thereto.

The present invention is directed against a conventional mask for an OLED thin-film encapsulation, which solves the problem that the mask for an OLED thin-film encapsulation in the conventional art: a continuous thin-film is formed on the substrate, the mask and the junction of the substrate and the mask; the continuous thin-film will be torn when the mask is raised, resulting in a large number of particles being generated; the particles will cause technological problems with the failure of thin-film encapsulation, an embodiment according to the present invention can solve this drawback.

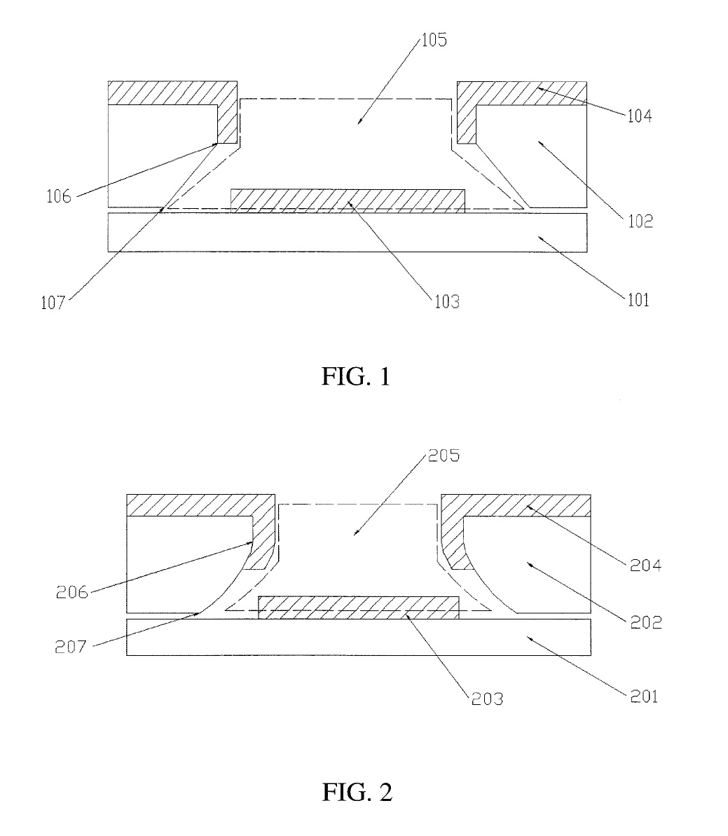

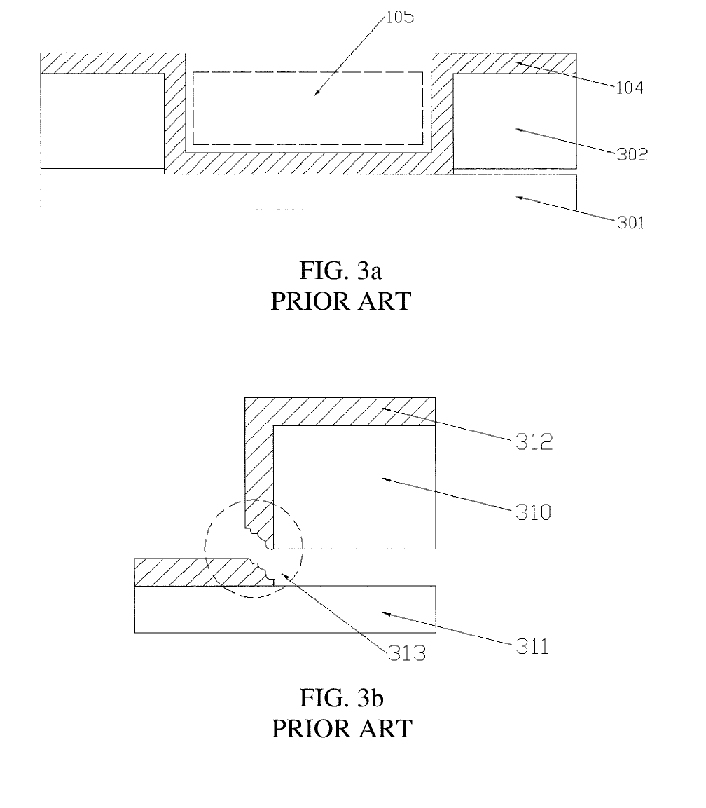

Referring now to FIG. 1. FIG. 1 illustrates a cross-sectional view of a mask for an OLED thin-film encapsulation according to a first embodiment of the present invention. The present invention provides a mask for an OLED thin-film encapsulation, comprising a hollow portion having an opening 105 configured to form a thin-film encapsulation layer 103 on a substrate 101; and a cover portion 102 configured to cover a non-thin-film encapsulation region on the substrate 101, wherein the cover portion 102 has a first surface contacting with the substrate 101, and a second surface away from the substrate 101; wherein the cover portion 102 has an edge surrounding the opening 105 and close to a side of the cover portion 102 contacting with the substrate 101, at least one portion of the edge of the cover portion 102 is formed with a chamfered corner.

An area of the first surface is smaller than an area of the second surface, and the second surface covers the first surface. The first surface is opposite to and parallel to the second surface. The edge surrounding the opening 105 has an inner wall formed with a first cutting point 106, and the first surface is formed with a second cutting point 107. A distance from the first cutting point 106 to the substrate 101 ranges from 15 to 20 um. The chamfered corner of the cover portion 102 is formed on the mask via the first cutting point 106 and the second cutting point 107. The opening 105 surrounded by the cover portion 102 has a structure which is a tapering shape. An end of the opening 105 closed to the substrate 101 is larger. The opposite end of the opening 105 is used to define the size of the thin-film encapsulation layer 103.

In a preferred embodiment, the chamfered corner is an equilateral orthogonal beveled corner, and an angle between a line from the first cutting point 106 to the second cutting point 107 and a vertical direction of the mask is 45°. In order to prevent the shadow effect, the mask needs to be closely attached on the substrate 101 so as to implement a thin-film encapsulation process. The thin-film encapsulation material passes through the openings 105 and forms the thin-film encapsulation layer 103 in a region of the substrate 101 corresponding to the opening 105. The thin-film encapsulation layer 103 includes an inorganic film and an organic film. Since the end of the opening 105 away from the substrate 101 is configured to define the size of the thin-film encapsulation layer 103, therefore, when one end of the opening 105 closed to the substrate 101 is larger than the other end, an area of the thin-film encapsulation layer 103 formed on the substrate 101 is smaller than an area of the end of the opening 105 closed to the substrate 101, A gap is formed between the thin-film encapsulation layer 103 and an inner wall of the cover portion surrounding the opening 105, the gap surrounds the thin-film encapsulation layer 103. In the film encapsulation process, the cover portion 102 is used to keep out the thin-film encapsulation material in the non-encapsulated area. Therefore, the thin-film encapsulation film 104 is attached on a surface of the cover portion 102, the cover portion 102 has the edge surrounding the opening 105 and close to the side of the cover portion 102 contacting with the substrate 101, at least one portion of the edge of the cover portion 102 is formed with a chamfered corner, the distance from the first cutting point 106 to the substrate 101 ranges from 15 to 20 um. In the current thin-film encapsulation, a thickness of the inorganic film generally ranges from 0.5 to 1 um, a thickness of the organic film is generally larger than 10 um. Therefore, another gap is formed between the thin-film encapsulation film 104 attached on the surface of the cover portion 102 and the thin-film encapsulation layer 103 formed on the substrate 101 corresponding to a region of the opening 105, and at the chamfered corner is in a disconnected state.

An angle of the chamfered corner is not limited in the present invention. The angle can be determined according to a specific thickness of the mask and a thickness of the thin-film encapsulation layer, as long as the embodiments can meet that the thin-film encapsulation layer disposed on the substrate, the mask plate and the thin-film encapsulation film attached on the mask are disconnected and a gap can be formed.

Refer now to FIG. 2. FIG. 2 illustrates a cross-sectional view of a mask for an OLED thin-film encapsulation according to a second embodiment of the present invention. The present invention provides a mask for an OLED thin-film encapsulation, comprising: a hollow portion having an opening 205 configured to form a thin-film encapsulation layer 203 on a substrate 201; and a cover portion 202 configured to cover a non-thin-film encapsulation region on the substrate 201, wherein the cover portion 202 has a first surface contacting with the substrate 201, and a second surface away from the substrate 201; wherein the cover portion 202 has an edge surrounding the opening 205 and close to a side of the cover portion 202 contacting with the substrate 201, at least one portion of the edge of the cover portion 202 is formed with a filleted corner.

An area of the first surface is smaller than an area of the second surface, and the second surface covers the first surface. The edge surrounding the opening 205 has an inner wall formed with a first cutting point 206, and the first surface is formed with a second cutting point 207. The filleted corner is a convex filleted corner. An angle between a line from the first cutting point 206 to the second cutting point 207 and a vertical direction of the mask is 45°. During implementing a thin-film encapsulation process, the thin-film encapsulation material passes through the openings 205 and forms the thin-film encapsulation layer 203 in a region of the substrate 201 corresponding to the opening 205. The thin-film encapsulation layer 203 includes an inorganic film and an organic film. Since the end of the opening 205 away from the substrate 201 is configured to define the size of the thin-film encapsulation layer 203, therefore, when one end of the opening 205 closed to the substrate 201 is larger than the other end, an area of the thin-film encapsulation layer 203 formed on the substrate 201 is smaller than an area of the end of the opening 205 closed to the substrate 201, A gap is formed between the thin-film encapsulation layer 203 and an inner wall of the cover portion surrounding the opening 205, the gap surrounds the thin-film encapsulation layer 203. In the film encapsulation process, the cover portion 202 is used to keep out the thin-film encapsulation material in the non-encapsulated area. Therefore, the thin-film encapsulation film 204 is attached on a surface of the cover portion 202, the cover portion 202 has the edge surrounding the opening 205 and close to the side of the cover portion 202 contacting with the substrate 201, at least one portion of the edge of the cover portion 202 is formed with a filleted corner, the distance from the first cutting point 206 to the substrate 201 ranges from 15 to 20 um. In the current thin-film encapsulation, a thickness of the inorganic film generally ranges from 0.5 to 1 um, a thickness of the organic film is generally larger than 10 um. Therefore, a gap is formed between the thin-film encapsulation film 204 attached on the surface of the cover portion 202 and the thin-film encapsulation layer 203 formed on the substrate 201 corresponding to a region of the opening 205, and at the filleted corner is in a disconnected state.

An angle of the filleted corner is not limited in the present invention. The angle can be determined according to a specific thickness of the mask and a thickness of the thin-film encapsulation layer, the filleted corner may also be a concave filleted corner, or other shapes, as long as the embodiments can meet that the thin-film encapsulation layer disposed on the substrate, the mask plate and the thin-film encapsulation film attached on the mask are disconnected and a gap can be formed.

The present invention further provides a mask for an OLED thin-film encapsulation, the mask comprises two or more of the hollow portions and one of the hollow portions is configured to correspondingly form one of the openings, thereby configured to form a plurality of thin-film encapsulation units on an OLED substrate. The mask surrounding the opening and close to a side of the mask contacting with the substrate, at least one portion of the mask is formed with a beveled corner. The beveled corner may be a chamfered corner, a filleted corner, or other shapes. The mask has a first surface contacting with the OLED substrate, and a second surface away from the OLED substrate. The mask surrounding the opening has an inner wall formed with a first cutting point, and the first surface surrounding the opening is formed with a second cutting point. A distance from the first cutting point to the OLED substrate ranges from 15 to 20 um. A gap is formed between a thin-film encapsulation film attached on a surface of a cover portion and the thin-film encapsulation units formed on the OLED substrate, and is in a disconnected state. Another gap is formed between one of the thin-film encapsulation units and an inner wall of the cover portion surrounding one of the openings, the gap is surrounding the thin-film encapsulation units. An angle of the beveled corner is not limited in the present invention. The angle can be determined according to a specific thickness of the mask and a thickness of the thin-film encapsulation layer.

The present invention has the following advantages: in comparison with the prior art, the present invention provides a mask for an OLED thin-film encapsulation, the thin-film formed on the substrate is disconnected with the mask and the thin-film attached on the mask, so as to prevent a continuous thin-film from being formed between the substrate and the mask, thereby preventing the continuous thin-film tearing and resulting in a large number of particles being generated when the mask is raised, thereby ensuring the effectiveness of thin-film encapsulation.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. A mask for an OLED (organic light-emitting diode) thin-film encapsulation, comprising:
a hollow portion having an opening configured to form a thin-film encapsulation layer on a substrate; and
a cover portion configured to cover a non-thin-film encapsulation region on the substrate, wherein the cover portion has a first surface contacting with the substrate, and a second surface away from the substrate;
wherein the cover portion has an edge surrounding the opening and close to a side of the cover portion contacting with the substrate, at least one portion of the edge of the cover portion is formed with a beveled corner; an area of the first surface is smaller than an area of the second surface; and the second surface covers the first surface.

2. The mask for the OLED thin-film encapsulation according to claim 1, wherein the beveled corner is a chamfered corner or a filleted corner.

3. The mask for the OLED thin-film encapsulation according to claim 2, wherein the edge surrounding the opening has an inner wall formed with a first cutting point, and the first surface is formed with a second cutting point.

4. The mask for the OLED thin-film encapsulation according to claim 3, wherein the beveled corner is an equilateral orthogonal beveled corner, and an angle between a line from the first cutting point to the second cutting point and a vertical direction of the mask is 45°.

5. The mask for the OLED thin-film encapsulation according to claim 3, wherein a distance from the first cutting point to the substrate ranges from 15 to 20 um.

6. The mask for the OLED thin-film encapsulation according to claim 2, wherein the mask for the OLED thin-film encapsulation is configured to form a gap between the thin-film encapsulation layer and an inner wall of the cover portion surrounding the opening.

7. The mask for the OLED thin-film encapsulation according to claim 6, wherein the gap surrounds the thin-film encapsulation layer.

8. The mask for the OLED thin-film encapsulation according to claim 6, wherein another gap is formed between the thin-film encapsulation layer formed on the substrate corresponding to a region of the opening and a thin-film encapsulation material attached on the cover portion.

9. The mask for the OLED thin-film encapsulation according to claim 1, wherein the mask comprises two or more of the hollow portions, and one of the hollow portions is configured to correspondingly form one of the openings.

10. A mask for an OLED (organic light-emitting diode) thin-film encapsulation, comprising:
a hollow portion having an opening configured to form a thin-film encapsulation layer on a substrate; and
a cover portion configured to cover a non-thin-film encapsulation region on the substrate, wherein the cover portion has a first surface contacting with the substrate, and a second surface away from the substrate;
wherein the cover portion has an edge surrounding the opening and close to a side of the cover portion contacting with the substrate, and at least one portion of the edge of the cover portion is formed with a beveled corner.

11. The mask for the OLED thin-film encapsulation according to claim 10, wherein the beveled corner is a chamfered corner or a filleted corner.

12. The mask for the OLED thin-film encapsulation according to claim 11, wherein the edge surrounding the opening has an inner wall formed with a first cutting point, and the first surface is formed with a second cutting point.

13. The mask for the OLED thin-film encapsulation according to claim 12, wherein the beveled corner is an equilateral orthogonal beveled corner, and an angle between a line from the first cutting point to the second cutting point and a vertical direction of the mask is 45°.

14. The mask for the OLED thin-film encapsulation according to claim 12, wherein a distance from the first cutting point to the substrate ranges from 15 to 20 um.

15. The mask for the OLED thin-film encapsulation according to claim 11, wherein the mask for the OLED thin-film encapsulation is configured to form a gap between the thin-film encapsulation layer and an inner wall of the cover portion surrounding the opening.

16. The mask for the OLED thin-film encapsulation according to claim 15, wherein the gap surrounds a peripheral of the thin-film encapsulation layer.

17. The mask for the OLED thin-film encapsulation according to claim 15, wherein another gap is formed between the thin-film encapsulation layer formed on the substrate corresponding to a region of the opening and a thin-film encapsulation material attached on the cover portion.

18. The mask for the OLED thin-film encapsulation according to claim 10, wherein the mask comprises two or more of the hollow portions, and one of the hollow portions is configured to correspondingly form one of the openings.
